(19) United States
(12) Patent Application Publication
(10) Pub. No.: US 2009/0298211 A1
(43) Pub. Date: Dec. 3, 2009

(54) METHOD FOR MANUFACTURING FLEXIBLE DISPLAY

(76) Inventors: Tae-Woong Kim, Suwon-si (KR); Dong-Un Jin, Suwon-si (KR); Hyung-Sik Kim, Suwon-si (KR); Hyun-Woo Koo, Suwon-si (KR); Hyun-Chul Lee, Suwon-si (KR); Yeon-Gon Mo, Suwon-si (KR)

Correspondence Address: CHRISTIE, PARKER & HALE, LLP, PO BOX 7068, PASADENA, CA, 91109-7068, US

(21) Appl. No.: 12/397,594

(22) Filed: Mar. 4, 2009

(30) Foreign Application Priority Data
May 28, 2008 (KR) 10-2008-0049712

(51) Int. Cl. H01L 51/56

(52) U.S. Cl. 438/35; 257/E51.022

(57) ABSTRACT

A method for manufacturing a flexible display is provided. A sacrificial layer is formed on a substrate support, the sacrificial layer having an absorptivity of 1 E+02 to 1 E+06 cm⁻¹ as a function of the wavelength of a laser. A flexible substrate is formed on the sacrificial layer. A device is formed on the flexible substrate. Laser irradiating is performed on a rear of the substrate support for detaching the sacrificial layer from the flexible substrate.

### CROSS-REFERENCE TO RELATED APPLICATIONS

This application claims priority to and the benefit of Korean Patent Application No. 10-2008-0049712, filed on May 28, 2008, in the Korean Intellectual Property Office, the entire content of which is incorporated herein by reference.

### BACKGROUND

1. Field of the Invention

The present invention relates to flexible displays, and, more particularly, to a method for manufacturing a flexible display.

2. Discussion of Related Art

In the modern information age, the importance of displays as visual information media has been emphasized. Further, the displays tend to have characteristics of less-power consumption, thinness, lightness, and high image quality.

Recently, a flexible display which is not damaged even though it is folded or rolled has emerged as a new technique in the display field. Such a flexible display is realized on a thin substrate such as plastic, and is not damaged even though it is folded or rolled like paper. Currently, a flexible display is realized by employing an organic light emitting device or liquid crystal display device, which can be manufactured to have a thickness of 1 mm or less.

In order to implement such a flexible display, it is essential to use a flexible substrate formed with plastic or metal foil such as stainless steel (SUS).

If a flexible display is manufactured using a plastic substrate, the plastic substrate may be bent or deformed by heat or pressure generated when a device is formed on the plastic substrate. The plastic substrate may even be damaged.

Accordingly, studies have been recently conducted to develop a method for preventing deformation of a substrate.

### SUMMARY OF THE INVENTION

In accordance with the present invention a method for manufacturing a flexible display is provided which prevents a flexible substrate from being deformed or damaged due to heat or pressure generated when a device is formed on the flexible substrate.

Further in accordance with the present invention a method for manufacturing a flexible display is provided which allows a delamination process of a flexible substrate and a substrate support attached to prevent deformation of the flexible substrate to be easily performed.

According to an aspect of the present invention, a sacrificial layer is formed with an absorptivity of 1 E+02 to 1 E+06 cm⁻¹ as a function of the wavelength of laser on a substrate support. A flexible substrate is formed on the sacrificial layer. A device is formed on the flexible substrate. A laser irradiating is performed on a rear of the substrate support for detaching the sacrificial layer from the flexible substrate.

The sacrificial layer may be any one selected from the group consisting of gallium indium zinc oxide (GIZO), indium tin oxide (ITO) and indium zinc oxide (IZO).

The laser may have a wavelength of 308 nm, and the coefficient of thermal expansion (CTE) of the flexible substrate may be 10 ppm/° C. or less. The flexible substrate may be formed of a plastic material, and the device may be an organic light emitting device.

According to another aspect of the present invention, a sacrificial layer is formed on a substrate support. A flexible substrate is formed on the sacrificial layer. A device is formed on the flexible substrate. Laser irradiating having a wavelength of 1064 nm is performed onto a rear of the substrate support for detaching the sacrificial layer from the flexible substrate.

The sacrificial layer may be any one selected from the group consisting of micro-crystalline silicon, molybdenum (Mo), Titanium (Ti) and ITO. The CTE of the flexible substrate is 10 ppmm/° C. or less. The flexible substrate may be formed of a plastic material, and the device may be an organic light emitting device.

As described above, according to the present invention, when a device is formed on a flexible substrate, a substrate support supporting the flexible substrate is disposed below the flexible substrate, so that it is possible to prevent the flexible substrate from being deformed or damaged.

Further, the substrate support is easily delaminated from the flexible substrate, so that it is possible to prevent characteristics of the device formed on the flexible substrate from being deteriorated.

### BRIEF DESCRIPTION OF THE DRAWINGS

FIGS. 1A, 1B, 1C, 1D and 1E are schematic cross-sectional views illustrating a method for manufacturing a flexible display according to an embodiment of the present invention.

FIG. 2 is a cross-sectional view of a flexible display according to an embodiment of the present invention.

FIG. 3 is a cross-sectional view of a flexible display according to an embodiment of the present invention.

### DETAILED DESCRIPTION

In the following detailed description, when an element is referred to as being “on” another element, it can be directly on the element or be indirectly on the element with one or more intervening elements interposed therebetween. Also, when an element is referred to as being “connected to” another element, it can be directly connected to the element or be indirectly connected to the element with one or more intervening elements interposed therebetween. Hereinafter, like reference numerals refer to like elements.

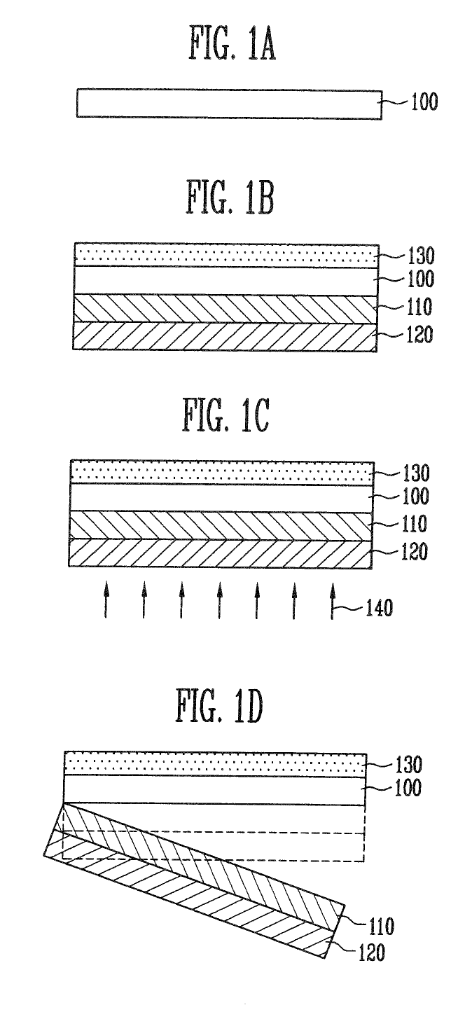

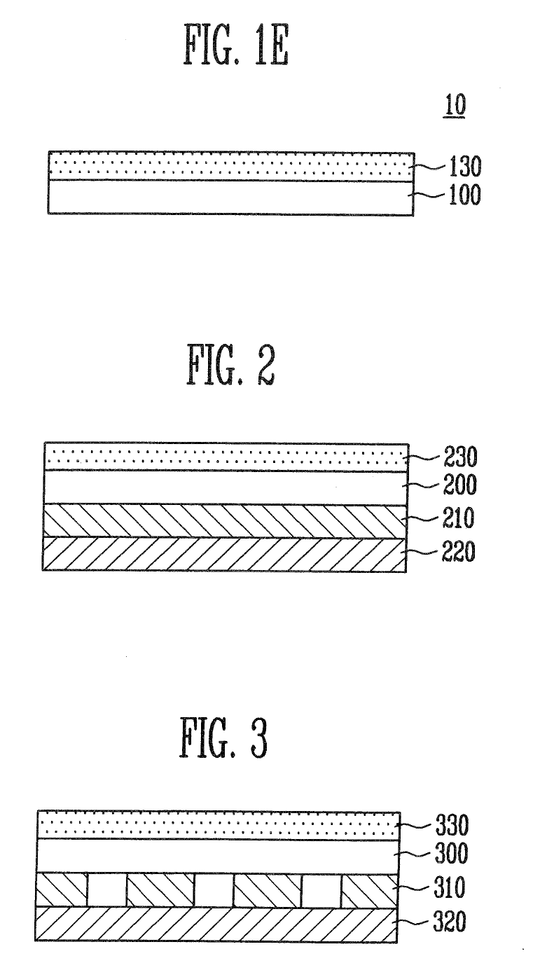

Referring to FIGS. 1A to 1E, in order to manufacture a flexible display 10 shown in FIG. 1E, a flexible substrate 100 is first prepared. The flexible substrate 100 may be a plastic material which can be subjected to spin coating, slit die coating or screen printing. In an exemplary embodiment, the flexible substrate 100 may be a high thermal-resistance plastic material (e.g., polyimide or polyarylate), which can endure a high processing temperature of over 350° C.

The flexible substrate 100 has a coefficient of thermal expansion (CTE) similar to that of a substrate support 120 formed of glass or a CTE of below 10 ppmm/° C. If the CTE of the flexible substrate 100 is not similar to that of the substrate support or exceeds 10 ppmm/° C., the flexible substrate 100 may be bent or deformed when a flexible device 130 is formed on the substrate support 120. Further, if the CTE of the flexible substrate 100 exceeds 10 ppmm/° C., the flexible substrate 100 may expand or contract in a high-temperature process, and therefore, the alignment of the device 130 deposited on the flexible substrate 100 may be distorted. Accordingly, the flexible substrate 100 of this embodiment has a CTE similar to that of the substrate support 120 or a CTE of below 10 ppmm/° C. The CTE of the substrate support 120 formed of glass is approximately 4 ppm/° C.

The thickness of the flexible substrate 100 may be 1 to 100 μm. If the thickness of the flexible substrate 100 is formed to below 1 μm, handling of the flexible substrate 100 is not easy, and the flexible substrate 100 may be easily damaged. Further, if the thickness of the flexible substrate 100 exceeds 100 μm, it is difficult to obtain uniformity of the flexible substrate 100.

If a device 130 (e.g., an organic light emitting device) is formed on the flexible substrate 100, the flexible substrate 100 may be bent or deformed due to heat or pressure generated in the process of forming the device 130. Accordingly, in this embodiment, the substrate support 120 is disposed below the flexible substrate 100 to prevent the flexible substrate 100 from being deformed.

Referring to FIG. 1B, the substrate support 120 is disposed below the flexible substrate 100 with a sacrificial layer 110 interposed therebetween. The substrate support 120 is used to prevent deformation of the flexible substrate 100 and in an exemplary embodiment is formed of glass having a small CTE.

When the device 130 formed on the flexible substrate 100 is completely manufactured, the substrate support 120 is delaminated from the flexible substrate 100. In order to delaminate the substrate support 120 from the flexible substrate 100, the sacrificial layer 110 is detached from the flexible substrate 100. Laser irradiation 140 onto a rear of the substrate support 120 detaches the sacrificial layer 110 from the flexible substrate 100. When the laser irradiation 140 is applied to the sacrificial layer 110 through the substrate support 120, the material constituting the sacrificial layer 110 decomposes so that the sacrificial layer 110 is detached from the flexible substrate 100. When the sacrificial layer 110 is detached from the flexible substrate 100, the substrate support 120 disposed beneath the sacrificial layer 110 is delaminated from the flexible substrate 100, as shown in FIG. 1D.

That is, in this embodiment, when the device 130 is formed on the flexible substrate 100, the substrate support 120 is disposed below the flexible substrate 100, so that deformation of the resultant flexible substrate 100, as shown in FIG. 1E, is prevented.

### Embodiment 1

Referring to FIG. 2, in order to manufacture a device 230 on a flexible substrate 200, a sacrificial layer 210 and a substrate support 220 are formed beneath the flexible substrate 200 as shown in FIG. 2. The sacrificial layer 210 and the substrate support 220 are formed to prevent the flexible substrate 200 from being deformed when the device 230 is formed on the flexible substrate 200.

A conventional sacrificial layer would be formed of amorphous silicon (a-si). However, if the sacrificial layer is formed of amorphous silicon, a high laser energy (about 700 to 750 mJ/cm²) is irradiated onto the sacrificial layer due to the high reflexibility of the amorphous silicon. As such, if a high laser energy is irradiated onto the sacrificial layer, a device formed above the sacrificial layer may be thermally damaged. That is, heat is conducted to the device formed on a flexible substrate, and therefore, characteristics of the device may be deteriorated. Further, if the sacrificial layer is formed of amorphous silicon, the flexible substrate detached from the sacrificial layer may be partially detached or torn out.

Accordingly, the sacrificial layer 210 having a high absorptivity as as function of the wavelength of laser is provided in this embodiment. In an exemplary embodiment the range of absorptivity as a function of the wavelength of laser is 1 E+02 to 1 E+06 cm⁻¹. That is, since the absorptivity as a function of the wavelength of laser irradiated onto a rear of the substrate support 220 is 1 E+02 to 1 E+06 cm⁻¹, the sacrificial layer 210 is detachable from the flexible substrate 200 even with a low laser energy (about 300 to 500 mJ/cm²). As such, the sacrificial layer 210 may be detached from the flexible substrate 200 with a low laser energy and can prevent the device 230 from being thermally damaged. Further, the flexible substrate 200 is not torn out but entirely detached from the sacrificial layer 210.

The sacrificial layer 210 may be any one selected from the group consisting of gallium indium zinc oxide (GIZO), indium tin oxide (ITO) and indium zinc oxide (IZO). In an exemplary embodiment, the thickness of the sacrificial layer 210 is 1 nm to 1 μm. If the thickness of the sacrificial layer 210 is below 1 nm, the sacrificial layer 210 is not uniformly formed. If the sacrificial layer 210 is not uniformly formed on a rear of the flexible substrate 200, the uniformity of the sacrificial layer 210 detached from the substrate 200 may be lowered. Further, if the thickness of the sacrificial layer 210 exceeds 1 μm, a processing time of the sacrificial layer 210 is increased.

For example, if laser having a wavelength of 308 nm is irradiated onto the rear of the substrate support 220, a portion of the photon energy of the laser is absorbed into the sacrificial layer 210, and the rest of the photon energy is conducted to the flexible substrate 200. The photon energy of the laser conducted to the flexible substrate 200 breaks bonds of organic materials in the flexible substrate 200 while being changed into thermal energy. As such, if the bonds of the organic materials in the flexible substrate 200 are broken, the sacrificial layer 210 is detached from the flexible substrate 200.

As described above, the sacrificial layer 210 is formed of a material having an absorptivity of 1 E+02 to 1 E+06 cm⁻¹ as a function of a wavelength of the laser, so that the sacrificial layer 210 can be detached from the flexible substrate 200 even with a low laser energy. Further, the sacrificial layer 210 is detached from the flexible substrate 200 with a low laser energy, so that it is possible to prevent damage due to the heat applied to the device 230 and the flexible substrate 200. Accordingly, characteristics of the device 230 delaminated from the sacrificial layer 210. This will be verified as seen in Table 1 below which shows characteristics of the device formed on the flexible substrate.

Specifically, in Table 1 (A) shows characteristics of the device in the state that the flexible substrate and the substrate support are joined together, and (B) shows characteristics of the device in the state that the flexible substrate is delaminated from the substrate support. At this time, the sacrificial layer in (A) and (B) is formed of any one selected from the group consisting of GIZO, ITO and IZO, having an absorptivity of 1 E+02 to 1 E+06 cm⁻¹ as a function of a wavelength of the laser, and laser having a laser energy of 300 to 500 mJ/cm⁻² is irradiated.

TABLE 1

| | | Vth | U_lin | U_sat | SS | | | |
|---|---|---|---|---|---|---|---|---|
| Flexible | Id | (threshold | (linear | (saturation | (subthreshold | | | On/Off |
| substrate | (Embodiment) | voltage) | mobility) | mobility) | slope | Ion | Ioff | Ratio |
| A (before | Embodiment 1 | 3.64 | 6.59 | 2.00 | 0.91 | 8.00.E−06 | 5.10.E−13 | 1.57.E+07 |
| delamination | | | | | | | | |
| | Embodiment 2 | 3.72 | 6.39 | 1.86 | 0.90 | 7.73.E−06 | 1.50.E−13 | 5.15.E+07 |
| | Embodiment 3 | 3.65 | 6.78 | 1.97 | 0.92 | 8.08.E−06 | 3.30.E−13 | 2.45.E+07 |
| | Embodiment 4 | 3.67 | 6.91 | 2.02 | 0.90 | 1.80.E−06 | 1.80.E−13 | 4.57.E+07 |
| | Mean | 3.67 | 6.67 | 1.96 | 0.91 | 8.01.E−06 | 2.93.E−13 | 3.43.E+07 |
| | Standard | 0.03 | 0.23 | 0.07 | 0.01 | 2.07.E−06 | 1.65.E−13 | 1.70.E+07 |
| | Deviation | | | | | | | |
| B (after | Embodiment 1 | 3.40 | 6.72 | 1.93 | 0.95 | 7.77.E−06 | 5.88.E−13 | 1.32.E+07 |
| delamination) | | | | | | | | |
| | Embodiment 2 | 3.49 | 6.52 | 1.83 | 0.93 | 7.81.E−06 | 3.42.E−13 | 2.29.E+07 |
| | Embodiment 3 | 3.32 | 5.80 | 1.91 | 0.91 | 6.46.E−06 | 1.65.E−13 | 3.91.E+07 |
| | Embodiment 4 | 3.43 | 6.97 | 2.04 | 0.95 | 8.39.E−06 | 6.25.E−13 | 1.34.E+07 |
| | Mean | 3.41 | 6.50 | 1.93 | 0.93 | 7.61.E−06 | 4.30.E−13 | 2.22.E+07 |
| | Standard | 0.07 | 0.50 | 0.09 | 0.02 | 8.16.E−06 | 2.17.E−13 | 1.22.E+07 |
| | Deviation | | | | | | | |

In Table 1, characteristics (Vth, U_lin, U_sat, SS, Ion, Ioff, and On/Off Ratio) of the device formed on the flexible substrate before delamination are similar to those of the device after delamination. That is, it can be seen that the device according to the present invention is not changed even though the flexible substrate is delaminated from the substrate support.

As such, in Embodiment 1, the sacrificial layer 210 is formed of any one selected from the group consisting of GIZO, ITO and IZO, having an absorptivity of 1 E+02 to 1 E+06 cm⁻¹ as a function of a wavelength of laser, so that the sacrificial layer 210 can be detached from the flexible substrate 200 even with a low laser energy. Accordingly, it is possible to prevent characteristics of the device formed on the flexible substrate 200 from being deteriorated. Here, a flexible display refers to the flexible substrate 200 and the device 230 formed on the flexible substrate 200.

The flexible display may be an organic light emitting diode display (OLED), a liquid crystal display (LCD), a field emission display (FED), a plasma display panel (PDP), an electro luminescent display (ELD), or a vacuum fluorescent display (VFD).

### Embodiment 2

Embodiment 2 as shown in FIG. 3 is the same as Embodiment 1, except for the material of a sacrificial layer 310 and the wavelength of laser irradiated onto the sacrificial layer 310.

While a 308 nm excimer laser can be irradiated onto a conventional sacrificial layer formed of amorphous silicon. However, the 308 nm excimer laser has high maintenance cost and high price. Accordingly, in this embodiment, the laser is irradiated onto the sacrificial layer 310 using 1064 nm Nd:YAG with low maintenance cost and low price.

However, if the laser is irradiated onto the sacrificial layer 310 formed of amorphous silicon using the 1064 nm Nd:YAG, the laser having a wavelength of 1064 nm is not sufficiently absorbed into the amorphous silicon. Therefore, the sacrificial layer 310 is not entirely detached from a flexible substrate 300.

Accordingly, the sacrificial layer 310 with a high absorptivity of laser having a wavelength of 1064 nm is provided in Embodiment 2. A material with a high absorptivity of laser having a wavelength of 1064 nm includes micro-crystalline silicon (uc(micro-crystalline)-Si), molybdenum (Mo), Titanium (Ti) and indium tin oxide (ITO).

In this embodiment, the sacrificial layer 310 is formed of any one selected from the group consisting of micro-crystalline silicon (uc(micro-crystalline)-Si), molybdenum (Mo), Titanium (Ti) and indium tin oxide (ITO).

A manufacturing process of a flexible display to which the sacrificial layer 310 of this embodiment, i.e., a delamination process of a substrate support 320 from the flexible substrate 300, will now be described.

In order to delaminate the substrate support 320 from the flexible substrate 300, a laser having a wavelength of 1064 nm is irradiated onto a rear of the substrate support 320 on which the flexible substrate 300 and a device 330 are sequentially laminated. If the laser is irradiated onto the rear of the substrate support 320, the laser is conducted to the sacrificial layer 310 through the substrate support 320. For example, if the sacrificial layer 310 is formed of micro-crystalline silicon (uc-Si), hydrogen (H) contained in the micro-crystalline silicon is reacted with the laser and exploded. Accordingly, the sacrificial layer 310 can be detached from the flexible substrate 300. If the sacrificial layer 310 is formed of any one of molybdenum (Mo), Titanium (Ti) and indium tin oxide (ITO), photon energy of the laser irradiated onto the sacrificial layer 310 is changed into thermal energy, and therefore, the sacrificial layer 310 is detached from the flexible substrate 300.

If the sacrificial layer 310 is detached from the flexible substrate 300, the substrate support 320 attached to a rear of the sacrificial layer 310 is delaminated from the flexible substrate 300.

As such, in Embodiment 2, the sacrificial layer 310 is formed of a material with a high absorptivity of laser having a wavelength of 1064 nm, so that the flexible substrate 300 can be completely detached from the sacrificial layer 310.

The sacrificial layer 310 as shown in FIG. 3 is formed into an island structure, unlike the sacrificial layer 210 (see FIG. 2) which is formed over the entire region between the substrate support 320 and the flexible substrate 300.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A method for manufacturing a flexible display, comprising:
forming a sacrificial layer on a substrate support, the sacrificial layer having an absorptivity of 1 E+02 to 1 E+06 cm⁻¹ as a function of laser wavelength;
forming a flexible substrate on the sacrificial layer;
forming a device on the flexible substrate; and
laser irradiating the substrate support for detaching the sacrificial layer from the flexible substrate.

2. The method as claimed in claim 1, wherein the sacrificial layer is any one selected from the group consisting of gallium indium zinc oxide, indium tin oxide and indium zinc oxide.

3. The method as claimed in claim 1, wherein the laser wavelength is 308 nm.

4. The method as claimed in claim 1, wherein the flexible substrate has a coefficient of thermal expansion of 10 ppmm/° C. or less.

5. The method as claimed in claim 1, wherein the flexible substrate comprises a plastic material.

6. The method as claimed in claim 1, wherein the device comprises an organic light emitting device.

7. A method for manufacturing a flexible display, comprising:
forming a sacrificial layer on a substrate support;
forming a flexible substrate on the sacrificial layer;
forming a device on the flexible substrate; and
irradiating onto the substrate support a laser having a wavelength of 1064 nm for detaching the sacrificial layer from the flexible substrate.

8. The method as claimed in claim 7, wherein the sacrificial layer is any one selected from the group consisting of micro-crystalline silicon, molybdenum, titanium and indium tin oxide.

9. The method as claimed in claim 7, wherein the flexible substrate has a coefficient of thermal expansion of 10 ppm/° C. or less.

10. The method as claimed in claim 7, wherein the flexible substrate comprises a plastic material.

11. The method as claimed in claim 7, wherein the device comprises an organic light emitting device.
